(19) United States
(12) Patent Application Publication
(10) Pub. No.: US 2020/0106194 A1
(43) Pub. Date: Apr. 2, 2020

(54) PLANAR ARRAY ANTENNA AND WIRELESS COMMUNICATION MODULE

(71) Applicant: HITACHI METALS, LTD., Minato-ku, Tokyo (JP)

(72) Inventor: Yasunori TAKAKI, Minato-ku, Tokyo (JP)

(21) Appl. No.: 16/609,231

(22) PCT Filed: May 25, 2018
(86) PCT No.: PCT/JP2018/020143

§ 371 Date: Oct. 29, 2019

(30) Foreign Application Priority Data
May 30, 2017 (JP) 2017-106692

(51) Int. Cl. H01Q 21/06; H01Q 13/10; H01Q 9/04; H01Q 1/42; H01Q 1/48; H01Q 23/00; H01P 5/10

(52) U.S. Cl. CPC H01Q 21/065; H01Q 13/106; H01Q 9/0414; H01Q 9/0435; H01L 2223/6627; H01Q 1/42; H01Q 1/48; H01Q 23/00; H01P 5/1015; H01Q 9/0457

(57) ABSTRACT

A planar array antenna is provided which can be used in broader bands. The planar array antenna includes a plurality of unit cells 50 which are one-dimensionally or two-dimensionally arranged. Each of the unit cells 50 includes a radiation portion 51 which includes a radiation conductor 11 and a first ground conductor layer 13 spaced away from the radiation conductor 11 and having a first slot 13c, and a power supply portion 52 which includes a strip conductor 14. The strip conductor 14 has a first end portion 14c which is supplied with an electric power from an external device and a second end portion 14d which is spaced away from the first end portion in a longitudinal direction. The distance between the first end portion 14c and the first ground conductor layer 13 is different from the distance between the second end portion 14d and the first ground conductor layer 13.

### TECHNICAL FIELD

The present disclosure relates to a planar array antenna and a wireless communication module.

### BACKGROUND ART

For high frequency wireless communication, a planar antenna is sometimes used. For example, Patent Documents Nos. 1 to 3 disclose planar antennas which have a slot in a conductor layer for power supply to a radiation conductor. Particularly, Patent Document No. 2 discloses a planar array antenna which includes plurality of planar antennas.

Specifically, Patent Document No. 2 discloses a planar array antenna which includes a plurality of strip conductors, a conductor layer with a plurality of slots, and a plurality of radiation conductors arranged so as to cover the respective slots.

### CITATION LIST

### Patent Literature

Patent Document No. Japanese Laid-Open Patent Publication No. 2013-201712

Patent Document No. 2: Japanese Laid-Open Patent Publication No. 6-291536

Patent Document No. 3: Japanese Laid-Open Patent Publication No. 7-046033

### SUMMARY OF INVENTION

### Technical Problem

Wireless communication has been applied to an increasing number of uses. Wireless communication has been utilized in various frequency bands. Thus, application to broader bands has been required. An object of the present application is to provide a planar array antenna which can be used in broader bands and a wireless communication module which includes the planar array antenna.

### Solution to Problem

A planar array antenna of the present disclosure is a planar array antenna including a plurality of unit cells which are one-dimensionally or two-dimensionally arranged, each of the unit cells including a radiation portion which includes a radiation conductor and a first ground conductor layer spaced away from the radiation conductor and having a first slot, and a power supply portion which includes a strip conductor, wherein the strip conductor has a first end portion which is supplied with an electric power from an external device and a second end portion which is spaced away from the first end portion in a longitudinal direction, and a distance between the first end portion and the first ground conductor layer is different from a distance between the second end portion and the first ground conductor layer.

The power supply portion may include a second ground conductor layer spaced away from the strip conductor, the strip conductor being located between the first ground conductor layer and the second ground conductor layer.

In each of the unit cells, the radiation conductor and the first slot may be aligned in a layer stacking direction.

A longitudinal direction of the strip conductor may not be parallel to a longitudinal direction of the first slot.

A distance between the second end portion and the first ground conductor layer may be shorter than a distance between the first end portion and the first ground conductor layer.

The strip conductor may include a plurality of planar strip portions and at least one via conductor portion. The plurality of planar strip portions may be located between the first end portion and the second end portion such that a longitudinal direction of each of the planar strip portions is in accord with a longitudinal direction of the strip conductor, and at least one of opposite ends of each of the planar strip portions may be connected with one of opposite ends of an adjacent planar strip portion via one of the plurality of via conductor portions. In the strip conductor, one of two adjoining planar strip portions located on the second end portion side may be closer to the first ground conductor layer than the other planar strip portion which is on the first end portion side.

The plurality of planar strip portions may have equal widths in a direction perpendicular to the longitudinal direction.

In at least a pair of adjoining two of the plurality of planar strip portions, a width in a direction perpendicular to the longitudinal direction of the planar strip portion on the second end portion side may be greater than a width in a direction perpendicular to the longitudinal direction of the planar strip portion on the first end portion side.

A width of at least one of the plurality of planar strip portions may be greater on the second end portion side than on the first end portion side.

The plurality of planar strip portions may be arranged parallel to the first ground conductor layer.

The strip conductor may include a planar strip portion. A longitudinal direction of the planar strip portion may be in accord with the longitudinal direction of the strip conductor. One of opposite ends of the planar strip portion on the second end portion side may be closer to the first ground conductor layer than the other end on the first end portion side.

The radiation portion may be located between the radiation conductor and the first ground conductor layer so as to be spaced away from the radiation conductor and from the first ground conductor layer, the radiation portion further including a planar conductor layer which has a second slot.

In each of the unit cells, the radiation portion may include a plurality of the planar conductor layers.

The second slot may have the same shape as the first slot.

The second slot may have a different shape from the first slot.

A distance between the first ground conductor layer and the planar conductor layer may be not more than 50 μm.

The planar conductor layer may be electrically coupled with the first ground conductor layer or the second ground conductor laver.

The planar conductor layer may be a floating conductor layer.

The power supply portion of each of the unit cells may further include a plurality of via conductors. The plurality of via conductors may be connected with the first ground conductor layer and the second ground conductor layer and arranged so as to surround the strip conductor.

Each of the unit cells may include a multilayer ceramic structure, and at least the planar conductor layer, the first ground conductor layer, the second ground conductor layer and the strip conductor may be buried in the multilayer ceramic structure.

A wireless communication module of the present disclosure includes: the planar array antenna as set forth in any of the foregoing paragraphs; and an active part electrically coupled with the planar array antenna.

### Advantageous Effects of Invention

According to the present disclosure, a planar array antenna which can be used in broader bands can be realized.

### BRIEF DESCRIPTION OF DRAWINGS

FIG. 1 is a plan view showing the general configuration of planar array antennas of the first and second embodiments.

FIG. 2 is an exploded perspective view showing a configuration of a unit cell of the planar array antenna of the first embodiment.

FIG. 3 is a cross-sectional view showing a configuration of the unit cell of the planar array antenna of the first embodiment.

FIG. 4(a) and FIG. 4(b) are a plan view and a cross-sectional view showing an example of a strip conductor.

FIG. 5(a) and FIG. 5(b) are a plan view and a cross-sectional view showing another example of a strip conductor.

FIG. 6(a) and FIG. 6(b) are a plan view and a cross-sectional view showing another example of a strip conductor.

FIG. 7(a) and FIG. 7(b) are a plan view and a cross-sectional view showing another example of a strip conductor.

FIG. 8(a) and FIG. 8(b) are a plan view and a cross-sectional view showing another example of a strip conductor.

FIG. 9 is a top view showing the positional relationship of the respective components in a unit cell of the planar array antenna of the first embodiment.

FIG. 10 is an exploded perspective view showing a configuration of a unit cell of the planar array antenna of the second embodiment.

FIG. 11 is a cross-sectional view showing a configuration of the unit cell of the planar array antenna of the second embodiment.

FIG. 12 is a cross-sectional view showing another configuration of the unit cell of the planar array antenna of the second embodiment.

FIG. 13 is a top view showing the positional relationship of the respective components in a unit cell of the planar array antenna of the second embodiment.

FIG. 14 is a cross-sectional view showing an example where a planar array antenna is realized by a multilayer ceramic substrate.

FIG. 15 is a cross-sectional view showing another example where a planar array antenna is realized by a multilayer ceramic substrate.

FIG. 16 is cross-sectional view showing a configuration example of a multilayer ceramic substrate which includes a wire circuit and a planar array antenna.

FIG. 17(a) is a schematic bottom view showing an embodiment of a wireless communication module FIG. 17(b) is a schematic cross-sectional view showing a wireless communication module mounted to a substrate.

FIG. 18 is a diagram showing the dimensions of a structure used in a simulation of the characteristics of a planar array antenna of an inventive example.

FIG. 19 is a graph showing the VSWR characteristic of a planar array antenna of an inventive example which was determined by calculation.

FIG. 20 is a graph showing the radiation characteristic of a planar array antenna of an inventive example which was determined by calculation.

FIG. 21 is a graph showing the radiation characteristic of a planar array antenna of an inventive example which was determined by calculation.

### DESCRIPTION OF EMBODIMENTS

A planar array antenna and a wireless communication module of the present disclosure can be used for wireless communication in, for example, the quasi-microwave band, the centimeter wave band, the quasi-millimeter wave band and the millimeter wave band. The wireless communication in the quasi-microwave band uses as the carrier wave an electric wave which has a wavelength of 10 cm to 30 cm and a frequency of 1 GHz to 3 GHz. The wireless communication in the centimeter wave band uses as the carrier wave an electric wave which has a wavelength of 1 cm to 10 cm and a frequency of 3 GHz to 30 GHz. The wireless communication in the millimeter wave band uses as the carrier wave an electric wave which has a wavelength of 1 mm to 10 mm and a frequency of 30 GHz to 300 GHz. The wireless communication in the quasi-millimeter wave band uses as the carrier wave an electric wave which has a wavelength of 10 mm to 30 mm and a frequency of 10 GHz to 30 GHz. In the wireless communication in these bands, the size of the planar antenna is of the order of several centimeters to sub-millimeters. For example, if a quasi-microwave/centimeter wave/quasi-millimeter wave millimeter wave wireless communication circuit is formed by a multilayer ceramic sintered substrate, a multiaxial antenna of the present disclosure can be mounted to the multilayer ceramic sintered substrate. Hereinafter, in the present embodiment, a planar array antenna is described with an example where the carrier wave of a quasi-microwave, centimeter wave, quasi-millimeter wave or millimeter wave has a frequency of 30 GHz and a wavelength λ of 10 mm unless otherwise specified.

In the present disclosure, if two directions are described as being “in accord”, it means that the angle between the two directions is approximately in the range of 0° to about 45°. The term “parallel” means that the angle between two planes, the angle between two lines, or the angle between a plane and a line is in the range of 0 to about 10°.

### First Embodiment

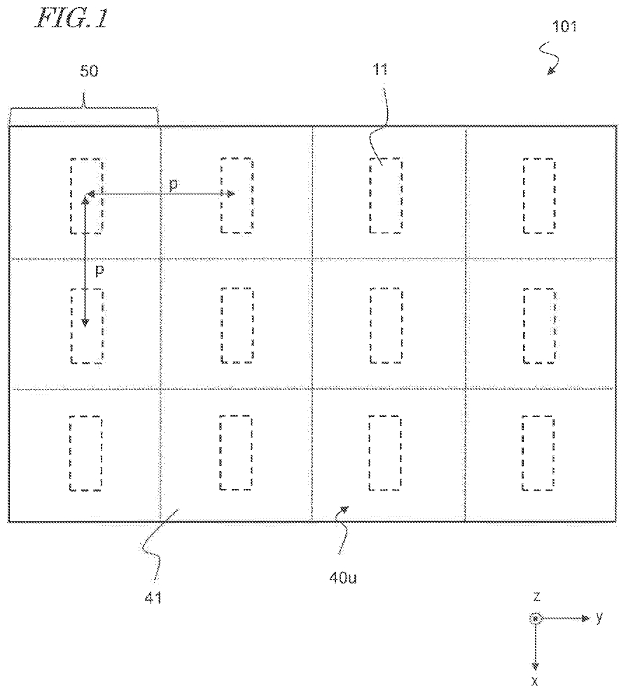

FIG. 1 is a plan view showing the first embodiment of a planar array antenna 101 of the present disclosure. The planar array antenna 101 includes a plurality of unit cells 50 which are represented by broken lines. Each of the unit cells 50 includes a radiation conductor 11 and forms a planar antenna which is capable of radiating an electromagnetic wave from the radiation conductor 11. Each of the unit cells 50 is provided in a dielectric 41. The plurality of unit cells are one-dimensionally or two-dimensionally arranged at pitch p. In the present embodiment, as shown in FIG. 1, the plurality of unit cells 50 are two-dimensionally arranged in the x direction and the direction. In the present embodiment, the radiation conductors 11 of the respective unit cells 50 are provided in the dielectric 41. That is, at a predetermined depth from the upper surface 40u of the dielectric 41, the radiation conductors 11 are arranged in an array in the x direction and the y direction. The radiation conductors 11 of the respective unit cells 50 may be on the same plane or may be at different heights in the z-axis direction.

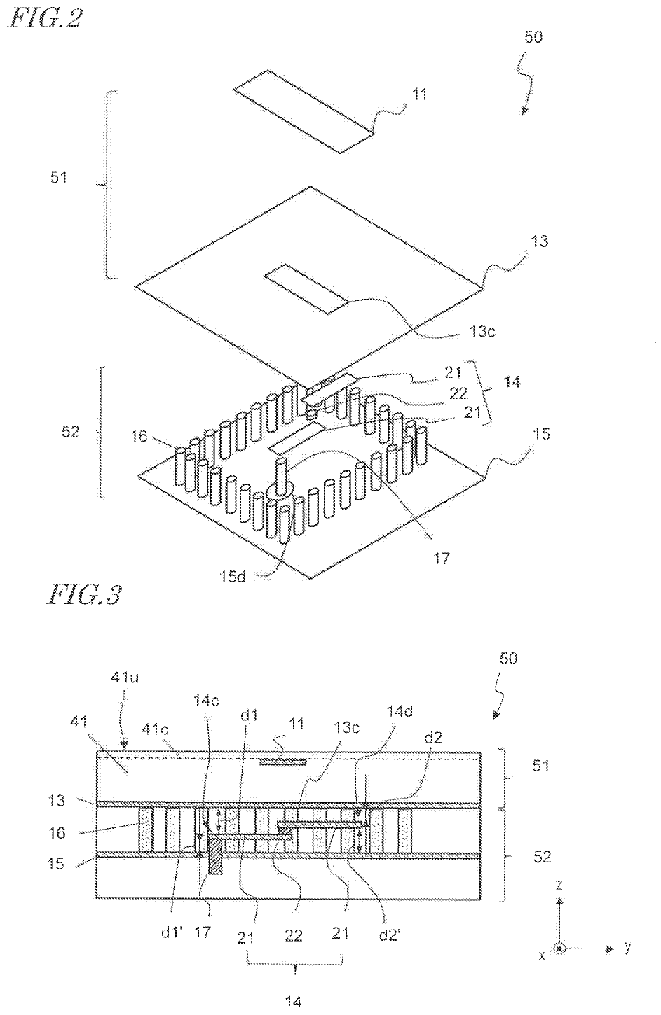

FIG. 2 is an exploded perspective view showing a configuration of the unit cell 50. FIG. 3 is a cross-sectional view of the unit cell 50. Each unit cell 50 includes a radiation portion 51 and a power supply portion 52. The power supply portion 52 and the radiation portion 51 are electromagnetically coupled. The radiation portion 51 receives a signal power supplied from the power supply portion 52, and an electromagnetic wave is radiated from the radiation conductor 11.

The radiation portion 51 includes a radiation conductor 11 and a first ground conductor layer 13. The radiation conductor 11 is spaced away from the first ground conductor layer 13. The first ground conductor layer 13 has an opening, which is referred to as “the first slot 13c”.

The power supply portion 52 includes a strip conductor 14 and a second ground conductor layer 15. The strip conductor 14 and the second ground conductor layer 15 are spaced away from each other. The strip conductor 14 is present between the first ground conductor layer 13 and the second ground conductor layer 15. The first ground conductor layer 13 and the strip conductor 14 are also spaced away from each other in the layer stacking direction.

For power supply to the strip conductor 14, the power supply portion 52 may include a via conductor 17. In this case, the second ground conductor layer 15 has an opening 15d. The via conductor 17 penetrates through the opening 15d, and one end of the via conductor 17 is connected with the strip conductor 14. The other end of the via conductor 17 is connected with a coupler, distributor, receiving circuit, transmitting circuit, or the like, on the lower surface side of the second ground conductor layer 15.

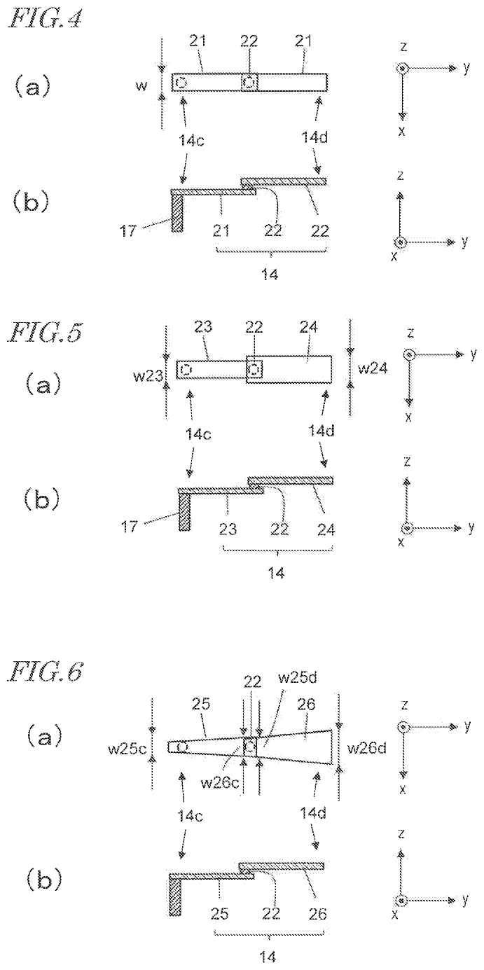

FIG. 4(a) and FIG. 4(b) are a plan view and a cross-sectional view of a strip conductor 14 to which a via conductor 17 is connected. The configuration of the strip conductor 14 is described with reference to FIG. 3 and FIG. 4.

The strip conductor 14 of the present embodiment has the longitudinal direction in the y direction in FIG. 3. The strip conductor 14 includes a first end portion 14c and a second end portion 14d which are at the opposite ends of the strip shape in the longitudinal direction. The second end portion 14d is spaced away from the first end portion 14c. Herein, the opposite ends and the end portions refer to portions in the vicinity of the opposite ends of a longitudinal member in the longitudinal direction. The first end portion 14c is connected with the via conductor 17 and is supplied with a signal power from an external device. As shown in FIG. 3, in the strip conductor 14, the distance d1 between the first end portion 14c and the first ground conductor layer 13 is different from the distance d2 between the second end portion 14d and the first ground conductor layer 13.

In the present embodiment, the distance d2 between the second end portion 14d and the first ground conductor layer 13 is smaller than the distance d1 between the first end portion 14c and the first ground conductor layer 13. That is, the relationship of d1>d2 is satisfied. The distance between the strip conductor 14 that is for supply of signal power from the power supply portion 52 to the radiation portion 51 and the first ground conductor layer 13 varies in the longitudinal direction, so that the gradient of the electromagnetic field in the dielectric space between the first ground conductor layer 13 and the second ground conductor layer 15 increases. Thus, a plurality of resonance modes are likely to occur, and the band of electromagnetic waves to be radiated is broadened.

As the electromagnetic field gradient between the first ground conductor layer 13 and the second ground conductor layer 15 increases, the gradient of the electromagnetic field distribution leaking from the first ground conductor layer 13 into the radiation conductor 11 increases. By optimizing these features and the shape of the radiation conductor 11, impedance matching is more easily achieved, and a planar array antenna can be realized which is capable of radiating electromagnetic waves over a broad band.

Now, attention is given to the second ground conductor layer 15. The distance d2′ between the second end portion 14d and the second ground conductor layer 15 is greater than the distance d1′ between the first end portion 14c and the second ground conductor layer 15. That is, the relationship of d1′<d2′ is satisfied. Also when the distance between the strip conductor 14 and the second ground conductor layer 15 varies in the longitudinal direction, an electric field distribution gradient occurs, and a plurality of resonance modes are more likely to occur. As a result, the band of electromagnetic waves to be radiated is broadened.

In the form shown in FIG. 3, the distance between the strip conductor 14 and the first ground conductor layer 13 decreases stepwise from the first end portion 14c to the second end portion 14d. So long as the distance of the strip conductor 14 from the first ground conductor layer 13 is different between the first end portion 14c and the second end portion 14d, the strip conductor 14 may have various forms and arrangements. For example, the strip conductor 14 may include a plurality of planar strip portions 21 and one or a plurality of via conductor portions 22. The planar strip portions 21 have a length smaller than the overall length in the longitudinal direction of the strip conductor 14. The planar strip portions 21 are provided between the first end portion 14c and the second end portion 14d such that the longitudinal direction of the planar strip portions 21 is in accord with the longitudinal direction of the strip conductor 14. At least one of the opposite ends of each of the planar strip portions 21 is connected with one of the opposite ends of an adjacent planar strip portion 21 via the via conductor portion 22. In the strip conductor 14, one of adjoining two planar strip portions 21 on the second end portion 14d side is closer to the first ground conductor layer 13 than the other planar strip portion 21 on the first end portion 14c side. Each of the planar strip portions 21 is arranged parallel to the first ground conductor layer 13. For example, the planar strip portions 21 are arranged stairlike when viewed in cross section.

In the form shown in FIG. 4(a) and FIG. 4(b), the widths w in a direction perpendicular to the longitudinal direction of the plurality of planar strip portions 21 are equal. However, the widths in a direction perpendicular to the longitudinal direction of the plurality of planar strip portions 21 may be different. For example, as shown in FIG. 5(a) and FIG. 5(b), the strip conductor 14 includes planar strip portions 23, 24 and a via conductor portion 22. The planar strip portion 23 is located on the first end portion 14c side. The planar strip portion 24 is located on the second end portion 14d side. The width w24 in a direction perpendicular to the longitudinal direction of the planar strip portion 24 is greater than the width w23 in a direction perpendicular to the longitudinal direction of the planar strip portion 23. In each of the planar strip portion 23 and the planar strip portion 24, the width in a direction perpendicular to the longitudinal direction is constant. In this case, also in a plane parallel to the first ground conductor layer 13, the electric field distribution gradient of a portion which includes the power supply portion 52 and the radiation portion 51 increases, and accordingly, a plurality of resonance modes are more likely to occur, and the band of electromagnetic waves to be radiated is broadened.

Alternatively, as shown in FIG. 6(a) and FIG. 6(b), the planar strip portions may have different widths in a direction perpendicular to the longitudinal direction. The strip conductor 14 includes planar strip portions 25, 26. In the planar strip portion 25 and the planar strip portion 26, the width w25d, w26d on the second end portion 14d side is greater than the width w25c, w26c on the first end portion 14c side.

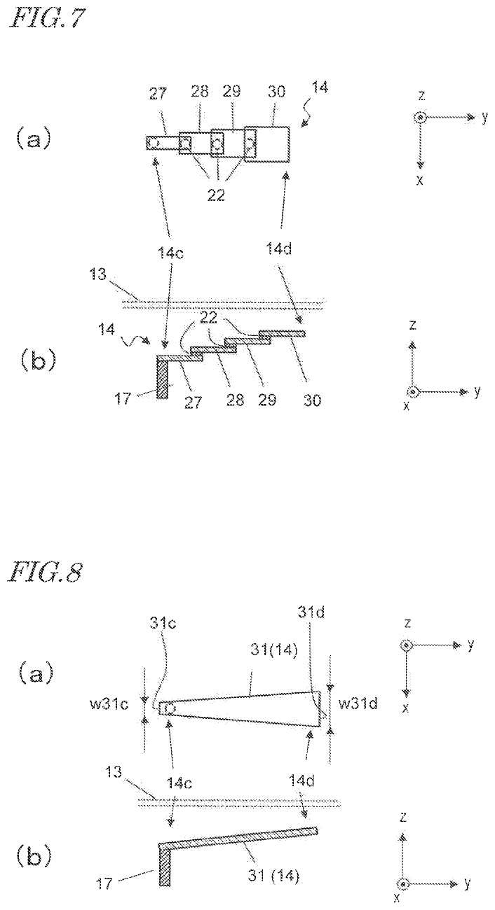

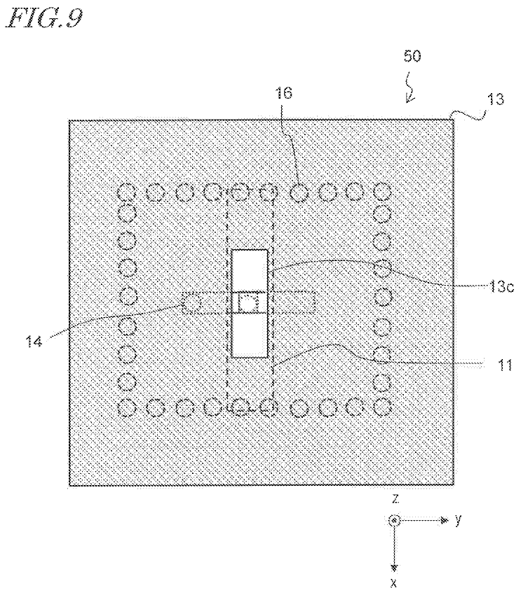

The number of planar strip portions included in the strip conductor 14 is not limited to two but may be three or more. As shown in FIG. 7(a) and FIG. 7(b), the strip conductor 14 includes planar strip portions 27, 28, 29, 30 and three via conductor portions 22. Each of the planar strip portions 27, 28, 29, 30 is, for example, arranged generally parallel to the first ground conductor layer 13. The planar strip portion 30 is located closer to the first ground conductor layer 13, represented by broken lines, than the planar strip portion 29. Likewise, the planar strip portion 29 is located closer to the first ground conductor layer 13 than the planar strip portion 28, and the planar strip portion 28 is located closer to the first ground conductor layer 13 than the planar strip portion 27.

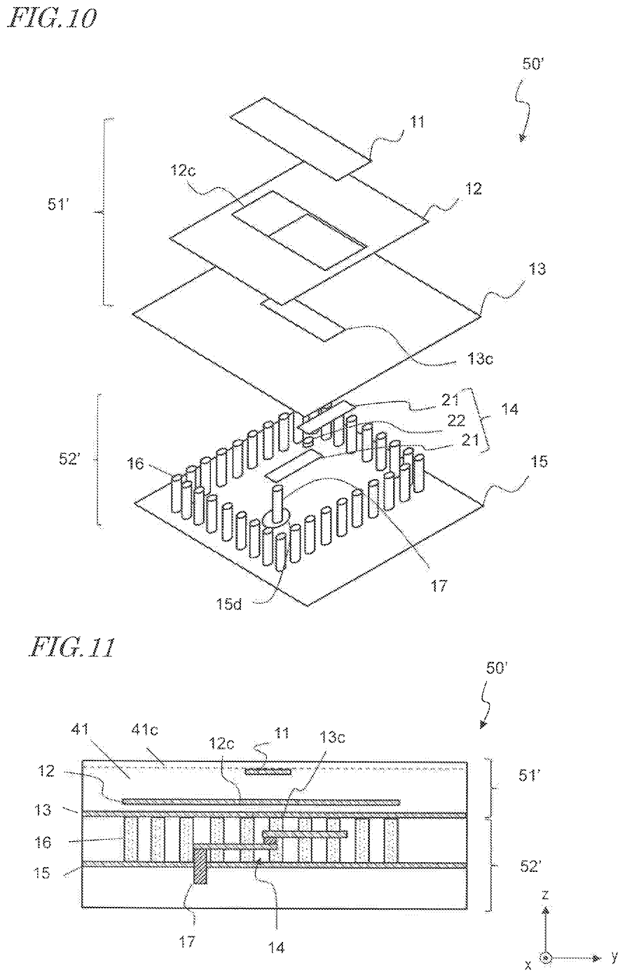

Alternatively, as shown in FIG. 8(a) and FIG. 8(b), the strip conductor 14 may include a single planar strip portion 31. The longitudinal direction of the planar strip portion 31 is in accord with the longitudinal direction of the strip conductor 14. One of the opposite ends of the planar strip portion 31 on the second end portion 14d side, i.e., the end portion 31d, is closer to the first ground conductor layer 13 (represented by broken lines) than the other end portion 31c on the first end portion 14c side. That is, the strip conductor 14 is not parallel to the first ground conductor layer 13 but is oblique with respect to the first ground conductor layer 13 in the longitudinal direction of the strip conductor 14. In the planar strip portion 31, the width wild on the second end portion 14d side is greater than the width w31c on the first end portion 14c side in a direction perpendicular to the longitudinal direction.

The strip conductors 14 shown in FIG. 4 to FIG. 7 can be suitably incorporated into a multilayer ceramic substrate when the dielectric 41 is realized by a multilayer ceramic structure as will be described later. On the other hand, for example, when the dielectric 41 is made of a resin, the planar array antenna 101 that includes the strip conductor 14 shown in FIG. 8 can be suitably produced by molding or the like.

As shown in FIG. 2 and FIG. 3, in the present embodiment, the power supply portion 52 further includes a plurality of via conductors 16. The via conductors 16 have a pole-like shape and are arranged so as to surround the strip conductor 14. One end of each via conductor 16 is connected with the first ground conductor layer 13, and the other end is connected with the second ground conductor layer 15.

The radiation conductor 11, the ground conductor layer 13, the strip conductor 14, the second ground conductor layer 15, the via conductors 16, the via conductor 17 and the via conductors 18 (described later) are made of an electrically-conductive material.

As shown in FIG. 3, a plurality of dielectric layers which form the dielectric 41 are present between the radiation conductor 11, the first ground conductor layer 13, the strip conductor 14 and the second ground conductor layer 15. The dielectric layers may be resin layers, glass layers, ceramic layers, cavities, etc. The radiation conductor 11, the first ground conductor layer 13, the strip conductor 14 and the second ground conductor layer 15 are buried in the dielectric 41. As previously described, the radiation conductor 11 is present inside the dielectric 41 at a predetermined depth from the upper surface 40u of the dielectric 41. That is, the radiation conductor 11 is covered with part (41c) of the dielectric 41. An example where the planar array antenna 101 is realized by a multilayer ceramic substrate will be described later.

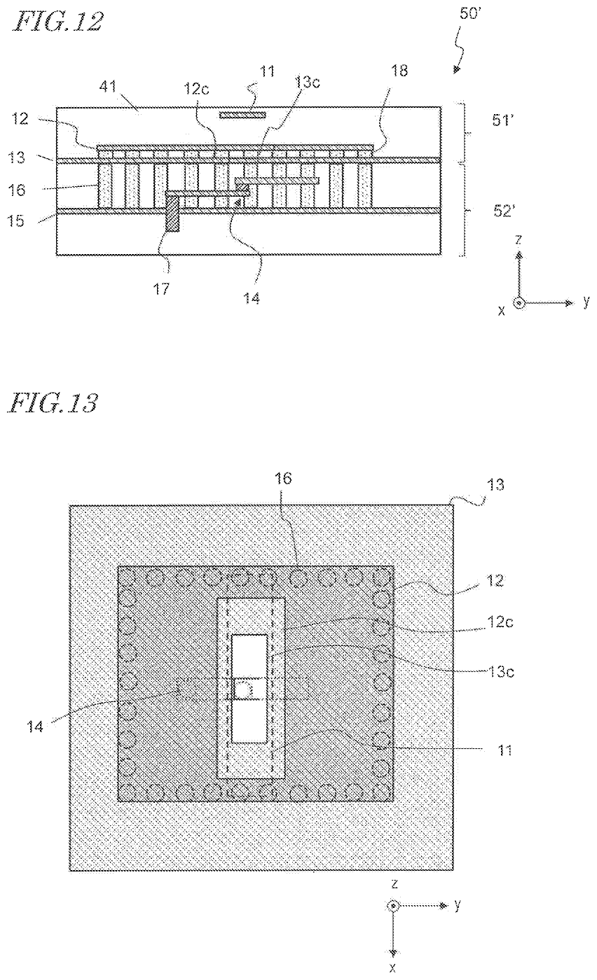

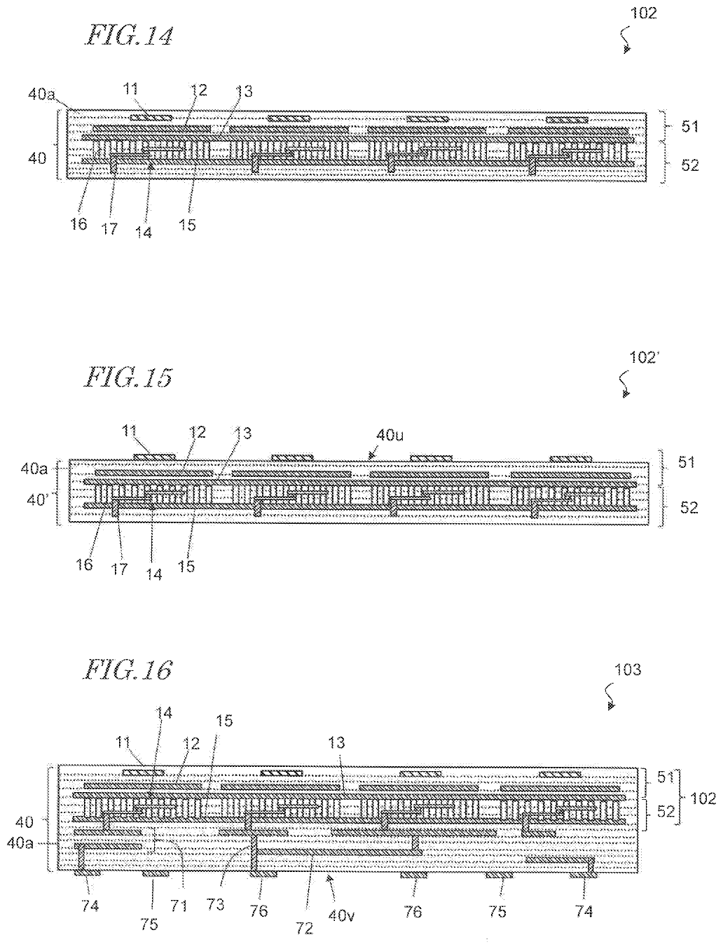

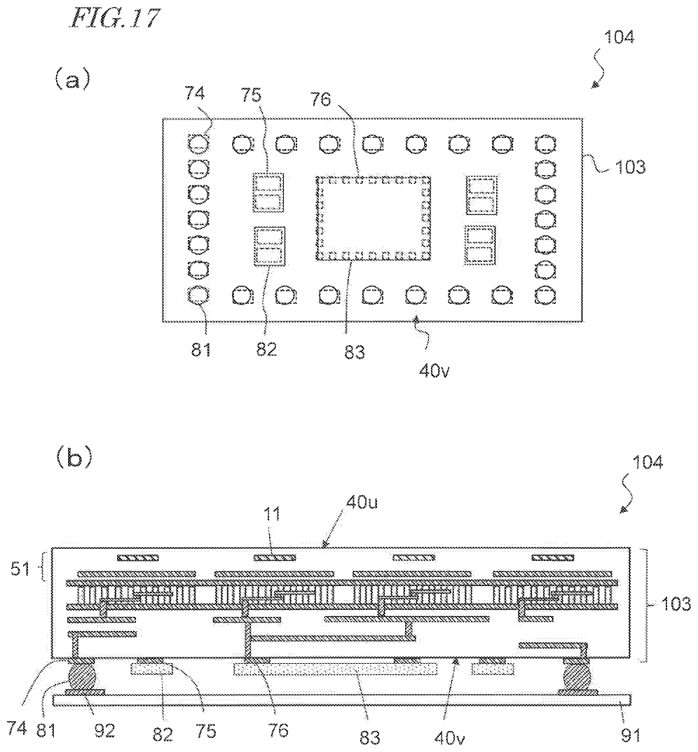

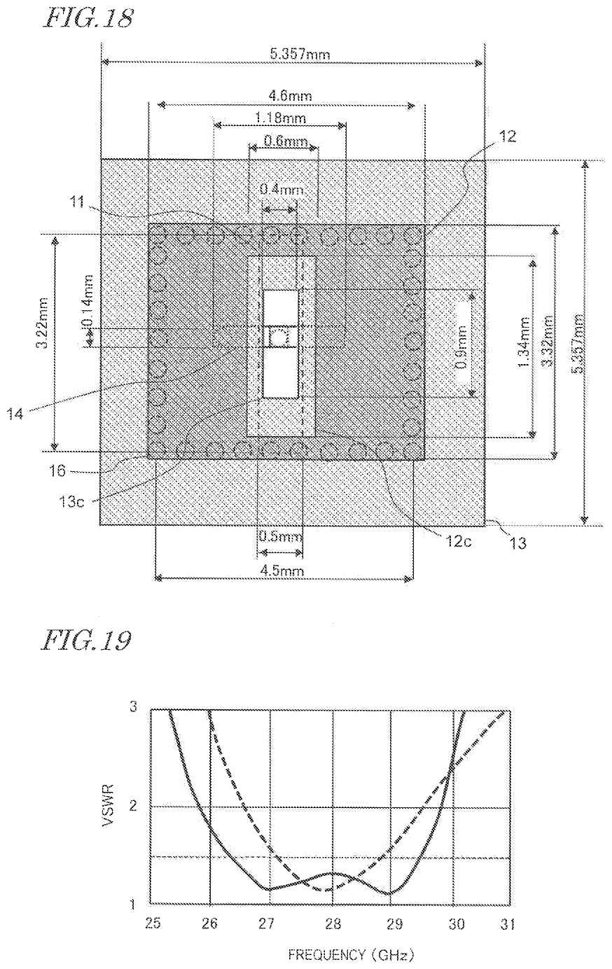

Next, the shape and arrangement of the respective components are described in detail. FIG. 9 is a schematic diagram of the respective structures of the unit cells 50 (see FIG. 1), which is seen in a direction perpendicular to the upper surface 40u of the multilayer ceramic structure 40 (see, for example, FIG. 15), i.e., in a direction normal to the upper surface 40u.

The radiation portion 51, which includes the radiation conductor 11 and the first ground conductor layer 13, is a radiation element which is capable of radiating an electric wave. The radiation portion 51 has a shape which is capable of achieving a required radiation characteristic and impedance matching. In the present embodiment, the radiation conductor 11 has a rectangular shape elongated in the x direction (which has a longitudinal dimension). The radiation conductor may have any other shape, such as square, circular, etc. For example, the radiation conductor 11 has lengths of 1.5 mm and 0.5 mm in the x direction and the direction, respectively.

As shown in FIG. 1, the pitch p of the radiation conductors 11 of the unit cells 50 is, for example, ½ of the wavelength λ₀ in the x direction and the y direction. Herein, λ₀ is the wavelength of the carrier wave in vacuum. λ_{d} is the wavelength of the carrier wave in the multilayer ceramic structure 40 that is a dielectric which will be described later.

The first slot 13c of the first ground conductor layer 13 has, for example, a rectangular shape. For example, the first slot 13c has lengths of 0.9 mm and 0.4 mm in the x direction and the y direction, respectively.

As shown in FIG. 9, the strip conductor 14 has, for example, a rectangular shape. The elongation direction of the strap conductor 14 and the elongation direction of the first slot 13c are preferably transversal with each other.

The first ground conductor layer 13 and the second ground conductor layer 15 of each unit cell 50 are respectively connected with the first ground conductor layers 13 and the second ground conductor layers 15 of adjacent unit cells 50 and preferably form integral electrically-conductive layers.

The distance an the layer stacking direction between the first ground conductor layer 13 and the second ground conductor layer 15 is, for example, 0.25 mm. The strip conductor 14 is, for example, located at the midpoint between the first ground conductor layer 13 and the second ground conductor layer 15 in the layer stacking direction. The distance between the radiation conductor 11 and the first ground conductor layer 13 is, for example, 0.4 mm.

In the planar array antenna 101, the signal power applied to a microstrip line which is formed by the strip conductor 14 and the second ground conductor layer 15 is electromagnetically coupled with the radiation conductor 11 via the first slot 13c of the first ground conductor layer 13. At this timing, the band of the radiated electromagnetic wave is broadened because the strip conductor 14 has the above-described configuration. Accordingly, the radiation characteristic and the signal reception characteristic of the planar array antenna 101 become broader.

if the strip conductor 14 is surrounded by the via conductors 16 at optimum positions, an electromagnetic field traveling in the y direction between the first ground conductor layer 13 and the second ground conductor layer 15 is likely to resonate, and the width in the x direction is optimized, so that impedance matching more easily achieved, the radiation efficiency improves, and a broader band can be realized. When using a dielectric whose dielectric constant is not less than 1, the optimized structure size of each antenna can be smaller than the arrangement pitch of the unit cells. When employing the above-described configuration, a small-size planar antenna of high radiation efficiency over a broad band is realized.

In the planar array antenna 101 of the present embodiment, the radiation conductor 11 is provided in the dielectric 41. Therefore, the radiation conductor 11 can be protected from oxidation which is attributed to external environments or damage or deformation which is attributed to external force.

From the viewpoint of protecting the radiation conductor 11, providing the radiation conductor 11 on the upper surface 40u of the dielectric 41 and forming an antioxidation plating layer over the radiation conductor 11 is a possible solution. However, in this case, the electrical conductivity of the radiation conductor 11 can decrease due to the plating layer, and the radiation characteristic can deteriorate. On the other hand, when the radiation conductor 11 is covered with the dielectric 41, the electrical conductivity of the radiation conductor 11 does not decrease. Thus, while the radiation characteristic is maintained at a level equal to or greater than that achieved with the plating layer, the achieved protection effect, such as protection against external force, can be higher than that achieved with the plating layer.

The thickness of a layer 41c of the dielectric 41 which covers the radiation conductor 11 is preferably not more than 70 μm when the relative permittivity of the dielectric 41 is, for example, about 3 to 15. The thickness of the layer 41c is preferably not more than 20 μm when the relative permittivity of the dielectric 41 is about 5 to 10.

In such a case, the achieved radiation efficiency can be equal to or higher than that achieved with an Au/Ni-plated. radiation conductor 11 which is usually used in planar array antennas. As the thickness of the layer 41c decreases, the loss is smaller. Therefore, the lower limit is not particularly determined from the viewpoint of the antenna characteristics. As will be described later, when the dielectric 41 is a multilayer ceramic structure, making uniform the thickness of the layer 41c can be difficult if the thickness is excessively small. Thus, it is preferred that the thickness of the layer 41c is, for example, 5 μm at which a uniform ceramic layer can be formed. That is, when the dielectric 41 is a multilayer ceramic structure, the thickness of the layer 41c is more preferably not less than 5 μm and not more than 70 μm, still more preferably not less than 5 μm and less than 20 μm.

### Second Embodiment

FIG. 10 and FIG. 11 are an exploded perspective view and a cross-sectional view of a unit cell 50′ in the second embodiment of the planar array antenna. The planar array antenna of the second embodiment is different from the unit cell 50 of the planar array antenna 101 of the first embodiment in that the radiation portion 51′ of the unit cell 50′ further includes a planar conductor layer 12.

The radiation portion 51′ includes the planar conductor layer 12 located between the radiation conductor 11 and the first ground conductor layer 13. The planar conductor layer 12 is spaced away from the radiation conductor 11 and from the first ground conductor layer 13 in the layer stacking direction. The planar conductor layer 12 has an opening, which is referred to as “the second slot 12c”.

The planar conductor layer 12 in the present embodiment is a floating conductor layer. That is, the planar conductor layer 12 is riot electrically coupled with the first ground conductor layer 13, the second ground conductor layer 15, or a conductor layer to which another reference potential is supplied. However, the planar conductor layer 12 may be grounded. Specifically, the planar conductor layer 12 may be electrically coupled with the first ground conductor layer 13, the second ground conductor layer 15, or a conductor layer to which another reference potential is supplied. For example, as shown in FIG. 12, the planar conductor layer 12 and the first ground conductor layer 13 may be coupled together by one or a plurality of via conductors 18. The radiation portion 51′ may include plurality of planar conductor layers 12. The planar conductor layer 12 is made of an electrically-conductive material.

FIG. 13 is a schematic view of the respective components of the unit cell 50′ which are viewed in a direction perpendicular to the upper surface 40u of the multilayer ceramic structure 40, i.e., in a direction normal to the upper surface 40u.

The radiation portion 51, which includes the radiation conductor 11, the planar conductor layer 12 and the first ground conductor layer 13, is a radiation element which is capable of radiating an electric wave. The radiation portion 51 has a shape which is capable of achieving a required radiation characteristic and impedance matching.

The second slot 12c of the planar conductor layer 12 may have the same shape as or may have a different shape from the first slot 13c of the first ground conductor layer 13. Herein, having the same shape does not include being similar but refers to being equal in shape and size (being congruent). Preferably, the radiation conductor 11, the first slot 13c and the second slot 12c at least partially overlap one another when viewed from top. More preferably, the radiation conductor 11, the first slot 13c and the second slot 12c are aligned in the layer stacking direction. Herein, being aligned means that the center of the first ground conductor layer 13, the center of the first slot 13c and the center of the second slot 12c are within the tolerance in the x direction and the y direction when viewed in the layer stacking direction.

When each of the first slot 13c and the second slot 12c has a rectangular shape, the elongation directions (longitudinal directions) of the rectangles are preferably in accord with each other. For example, the first slot 13c has lengths of 0.9 mm and 0.4 mm in the x direction and the direction, respectively.

When the planar conductor layer 12 is a floating layer, the planar conductor layer 12 may be independent and not connected with the planar conductor layers 12 of adjacent unit cells 50′. In this case, it is preferred that, when viewed from top, the planar conductor layer 12 covers a region in which the via conductors 16 surrounding the strip conductor 14 are provided.

When the planar conductor layer 12 is grounded, the planar conductor layer 12 may be connected with the planar conductor layers 12 of adjacent unit cells 50′ via unshown via conductors and/or wiring layers. Alternatively, the planar conductor layer 12 may form an integral electrically-conductive layer together with the planar conductor layers 12 of adjacent unit cells 50′ and may be coupled with the ground potential via via conductors and/or wiring layers.

The space between the planar conductor layer 12 and the first ground conductor layer 13 is preferably small. Specifically, the distance between the planar conductor layer 12 and the first ground conductor layer 13 is preferably not more than 50 μm, more preferably not more than 25 μm.

In the planar array antenna 101, the signal power applied to a microstrip line which is formed by the strip conductor 14 and the second ground conductor layer 15 is electromagnetically coupled with the radiation conductor 11 via the first slot 13c of the first ground conductor layer 13. At this timing, due to the presence of the planar conductor layer 12, complex resonance occurs between the radiation conductor 11 and the first ground conductor layer 13 that has the first slot 13c and the planar conductor layer 12 that has the second slot 12c, so that the band of the radiated electromagnetic wave becomes broader. Accordingly, the radiation characteristic and the signal reception characteristic of the planar array antenna 101 become still broader. Particularly, by shortening the distance between the planar conductor layer 12 and the first ground conductor layer 13, equivalent electromagnetic fields are produced in the planar conductor layer 12 and the first ground conductor layer 13 from the strip conductor 14, and thus, the effect of increasing the band width is easily achieved.

### Third Embodiment

Hereinafter, an example where the planar array antenna of the first embodiment or the second embodiment is realized by a multilayer ceramic substrate is described. In the present embodiment, an example where the dielectric 41 of the planar array antenna of the second embodiment is realized by a multilayer ceramic structure is described. FIG. 14 schematically shows a cross section of a multilayer ceramic substrate 102. The multilayer ceramic substrate 102 includes a multilayer ceramic structure 40, and a radiation conductor 11, a planar conductor layer 12, a first ground conductor layer 13, a strip conductor 14, a second ground conductor layer 15, via conductors 16 and via conductors 17 which are buried in the multilayer ceramic structure 40.

The multilayer ceramic structure 40 includes plurality of ceramic layers 40a as represented by broken lines. The aforementioned components are spaced away from one another by one or two or more of the ceramic layers 40a. The positions of the broken lines are schematically shown, and the number of ceramic lavers 40a included in the multilayer ceramic substrate is not necessarily precisely shown. The via conductors 16 and the via conductors 17 are present in the through holes in the ceramic layers 40a.

The first slot 13c and the second slot 12c (see FIG. 10 and FIG. 13) may be cavities or may be filled with part of the ceramic layers 40a. When the first slot 13c and the second slot 12c are filled with part of the ceramic layers 40a, the adhesion between the ceramic layers 40a improves, and the strength of the multilayer ceramic structure 40 can be increased.

In the multilayer ceramic structure 40, the boundaries between the ceramic layers 40a can be indefinite. In this case, for example, when a non-ceramic component such as the first ground conductor layer 13 is present between two ceramic layers, the position of the first ground conductor layer 13 can be made corresponding to the boundary between the two ceramic layers. The ceramic layers 40a may correspond to ceramic green sheets before sintering of the ceramic or may correspond to two or more layers of ceramic green sheets.

The thickness of each of the ceramic layers 40a is for example not less than 1 μm and not more than 15 mm, preferably not less than 15 μm and not more than 1 mm. Thereby, a planar array antenna of quasi-microwave, centimeter wave, quasi-millimeter wave and millimeter wave bands can be constructed.

The radiation conductor 11 may be present on the upper surface of the multilayer ceramic structure. The multilayer ceramic substrate 102′ shown in FIG. 15 is different from the multilayer ceramic substrate 102 in that the radiation conductor 11 is present on the upper surface 40′u of the multilayer ceramic structure 40′. Since the radiation conductor 11 exposed to the external environment, higher radiation efficiency can be realized. A product manufactured using a multilayer ceramic substrate of this configuration is suitable to a case where it is used under the conditions that damage or deformation which is attributed to, for example, environmental factors, such as temperature and humidity, or physical contact is unlikely to occur. More specifically, a product of this configuration is suitably used in a case where, for example, such conditions that it is encapsulated in vacuum or encapsulated in an inert gas when used or such conditions that a radiation conductor is formed using a metal which is unlikely to be corroded by oxidation or sulfidation are met.

The multilayer ceramic substrate may include other components than the planar array antenna 101. For example, as shown in FIG. 16, the multilayer ceramic substrate 103 further includes a plurality of ceramic layers 40a below the second ground conductor layer 15. The multilayer ceramic substrate 103 further includes a passive-parts pattern 71, a wiring pattern 72, and an electrically-conductive via 73 provided in the plurality of ceramic layers 40a. The passive-parts pattern 71 is, for example, an electrically-conductive layer or a ceramic layer which has a predetermined resistance value, and forms an inductor, capacitor, resistance, coupler, distributor, filter, power supply, etc. The electrically-conductive via 73 and the wiring pattern 72 are connected with the passive-parts pattern, the ground conductor, etc., to form a predetermined circuit.

On the lower surface 40v of the multilayer ceramic structure 40, for example, electrodes 74 for connection with an external substrate, electrodes 75 for connection of passive parts, and electrodes 76 for connection of active parts such as integrated circuit are provided. The strip conductor 14 may be electrically coupled with any of the electrodes 74, 75, 76 via an electrically-conductive via located at an unshown position.

The aforementioned components provided between the plurality of ceramic layers 40a which are on the lower surface side than the second ground conductor layer 15 form a wire circuit which includes passive parts. The passive parts and integrated circuits are connected with the above-described electrodes of the wire circuit, whereby a wireless communication circuit is constructed.

When the planar array antenna 101 is realized by a multilayer ceramic substrate, it is possible to simultaneously fire respective ceramic layers and conductive layers including the radiation conductor 11 and the planar conductor layer 12. That is, the multilayer ceramic substrate 103 may be a co-fired ceramic substrate. The co-fired ceramic substrate may be a low temperature co-fired ceramic (LTCC) substrate or may be a high temperature co-fired ceramic (HTCC) substrate. From the viewpoint of high frequency characteristics, using a low temperature co-fired ceramic substrate can be preferred. The ceramic materials and electrically-conductive materials which are used for ceramic layers, radiation conductors, ground conductors, strip conductors, passive-parts patterns, wiring patterns, electrically-conductive vias of the multilayer ceramic structure are selected according to the firing temperature, uses, and the frequency of wireless communication. An electrically-conductive paste for formation of radiation conductors, ground conductors (specifically, ground conductor layers), strip conductors, passive-parts patterns, wiring patterns and electrically-conductive vias, and green sheets for formation of ceramic layers of the multilayer ceramic structure are simultaneously fired (co-fired). When the co-fired ceramic substrate is a low temperature co-fired ceramic substrate, a ceramic material and an electrically-conductive material which can be sintered in a temperature range of about 800° C. to about 1000° C. are used. For example, a ceramic material which contains Al, Si and Sr as major constituents and at least one of Ti, Bi, Cu, Mn, Na and K as a minor constituent, a ceramic material which contains Al, Si and Sr as major constituents and at least one of Ca, Pb, Na and K as a minor constituent, a ceramic material which contains Al, Mg, Si and Gd, and a ceramic material which contains Al, Si, Zr and Mg can be used. An electrically-conductive material which contains Ag or Cu can be used. The dielectric constant of the ceramic material is about 3 to 15. When the co-fired ceramic substrate is a high temperature co-fired multilayer ceramic substrate, a ceramic material which contains Al as a major constituent and an electrically-conductive material which contains W (tungsten) or Mo (molybdenum) can be used.

More specifically, various materials can be used as the LTCC material. For example, an Al—Mg—Si—Gd—O based dielectric material of a low dielectric constant (relative permittivity: 5 to 10), a dielectric material consisting of a Mg₂SiO₄ crystalline phase and Si—Ba——La—B—O based glass, an Al—Si—Sr—O based dielectric material, an Al—Si—Ba—O based dielectric material, and a Bi—Ca—Nb—O based dielectric material of a high dielectric constant (relative permittivity: 50 or higher) can be used.

For example, when the Al—Si—Sr—O based dielectric material contains oxides of Al, Si, Sr and Ti as major constituents and the major constituents, Al, Si, Sr and Ti, are converted to Al₂O₃, SiO₂, SrO and TiO₂, the Al—Si—Sr—O based dielectric material preferably contains Al₂O₃: 10 to 60 mass %, SiO₂: 25 to 60 mass %, SrO: 7.5 to 50 mass %, and TiO₂: not, more than 20 mass (including 0). The Al—Si—Sr—O based dielectric material preferably further contains at least one of the group consisting of Bi, Na, K and Co as a minor constituent in the range of 0.1 to 10 parts by mass when converted to Bi₂O₃, 0.1 to 5 parts by Mass when converted to Na₂O, 0.1 to 5 parts by mass when converted to K₂O, 0.1 to 5 parts by mass when converted to CoO, with respect to 100 parts by mass of the major constituents. The Al—Si—Sr—O based dielectric material preferably further contains at least one of the group consisting of Cu, Mn and Ag in the range of 0.01 to 5 parts by mass when converted to CuO, 0.01 to 5 parts by mass when converted to Mn₃O₄, and Ag in the range of 0.01 to 5 parts by mass. In addition, the Al—Si—Sr—O based dielectric material can contain unavoidable impurities.

In the multilayer ceramic structure 40, the plurality of ceramic layers 40a may have the same composition and may be made of the same material. Alternatively, for the purpose of increasing the radiation efficiency of the planar antenna, a ceramic layer near the radiation conductor 11 of the multilayer ceramic structure 40 may have a different composition from that of the lower ceramic layers and may be made of a different material. When that layer has a different composition, the layer can have a different dielectric constant, and the radiation efficiency can be improved.

The radiation conductor 11 may be covered with a resin or glass layer other than the ceramic layers. Alternatively, the multilayer ceramic structure 40 and a circuit board which is made of a resin or glass may be combined to construct a complex substrate.

The co-fired ceramic substrate can be produced by the same production method as that used for LTCC substrates or HTCC substrates.

For example, firstly, a ceramic material which contains the above-described elements is prepared and, when necessary, calcinated at for example 700° C. to 850° C. and pulverized into grains. Glass powder, an organic binder, a plasticizer and a solvent are added to the ceramic material, resulting in a slurry of the mixture of these materials. When the ceramic layers are made of different materials for the purpose of for example achieving different dielectric constants, two types of slurries which contain different materials are prepared. Powder of the above-described electrically-conductive material is mixed with an organic binder and a solvent, resulting in an electrically-conductive paste.

A slurry layer of a predetermined thickness is formed on a carrier film using a doctor blade method, a rolling (extrusion) method, a printing method, an ink jet coating method, a transfer method, or the like, and then dried. The resultant slurry layer is cut into ceramic green sheets.

Then, according to the circuits which are to be constructed in the co-fired ceramic substrate, via holes are formed in a plurality of ceramic green sheets using laser, mechanical puncher, or the like, and the respective via holes are filled with an electrically-conductive paste by a screen printing method. In this step, the pattern of the via conductors 16 and the via conductors 17 is also formed. An electrically-conductive paste is printed on the ceramic green sheets by screen printing, whereby a wiring pattern, a passive-parts pattern, and a pattern of the radiation conductor 11, the planar conductor layer 12, the first ground conductor layer 13, the strip conductor 14 and the second ground conductor layer 15 are formed in the ceramic green sheets.

The ceramic green sheets to which the above-described electrically-conductive paste is provided are sequentially stacked up while being preparatorily pressure-bonded, whereby a green sheet multilayer structure is formed. Thereafter, the binder removed from the green sheet multilayer structure, and the resultant green sheet multilayer structure from which the binder has been removed is baked, whereby a co-fired ceramic substrate is completed.

The thus-produced co-fired ceramic substrate includes a wire circuit for wireless communication, passive parts, and a planar array antenna. Therefore, by mounting a chip set for wireless communication to a co-fired ceramic substrate, wireless communication module which also includes an antenna is realized.

When the ceramic layer at the surface of the multilayer ceramic structure entirely covers the radiation conductor, the ceramic layer can protect the radiation conductor from the external environment and external force and can prevent the radiation efficiency from decreasing and the antenna properties from varying.

In the planar array antenna described in the present embodiment, the shape, number and arrangement of the radiation conductors, the planar conductor layer, the first ground conductor layer, the second ground conductor layer and the strip conductors are merely schematic examples. For example, some of the plurality of radiation conductors may be provided at the interface of ceramic layers located at different distances from the ground conductor. The radiation conductors may have a slot. The planar array antenna may include conductors to which the power is not to be supplied in addition to the radiation conductors. Such conductors may be stacked up with the radiation conductors and ceramic layers being interposed therebetween.

### Fourth Embodiment

An embodiment of a wireless communication module is described. FIG. 17(a) is a schematic bottom view showing an embodiment of a wireless communication module of the present disclosure. FIG. 17(b) is a schematic cross-sectional view showing a wireless communication module mounted to a substrate. The wireless communication module 104 includes the multilayer ceramic substrate 103 of the second embodiment, solder bumps 81, a passive part 82 and an active part 83. The solder bumps 81 are provided on electrodes 74 which are located at the lower surface 40v of the multilayer ceramic substrate 103. The passive part 82 is, for example, a chip capacitor, a chip inductor, a chip resistor, or the like, and is bonded to an electrode 75 by soldering or the like. The active part 83 is, for example, a chip set for wireless communication, which is a receiving circuit, transmitting circuit, A/D converter, D/A converter, baseband processor, media access controller, or the like, and is bonded to an electrode 76 by soldering or the like.

The wireless communication module 104 is, for example, bonded face down to a circuit board 91 which has an electrode 92 by chip bonding, i.e., such that the passive part 82 and the active part 83 face the circuit board 91. The electrodes 92 of the circuit board 91 are electrically coupled with the electrodes 74 of the multilayer ceramic substrate 103 via the solder bumps 81, whereby the multilayer ceramic substrate 103 is electrically coupled with an external power supply circuit or other modules.

In the wireless communication module 104 mounted to the circuit board 91, the radiation conductor 11 on the upper surface 40u side of the multilayer ceramic substrate 103 is located opposite to the lower surface 40v on which the circuit board 91 faces. Therefore, the wireless communication module 104 is capable of radiating electric waves in quasi-microwave, centimeter wave, quasi-millimeter wave and millimeter wave bands from the radiation portion 51 without being affected by the passive part 82 and the active part 83 or by the circuit board 91 and is capable receiving at the radiation portion 51 incoming electric waves in quasi-microwave, centimeter wave, quasi-millimeter wave and millimeter wave bands. Thus, a wireless communication module can be realized which has a broad band antenna, which is small in size, and which is capable of surface mounting.

(Example of Calculation of Characteristic of Planar Array Antenna)

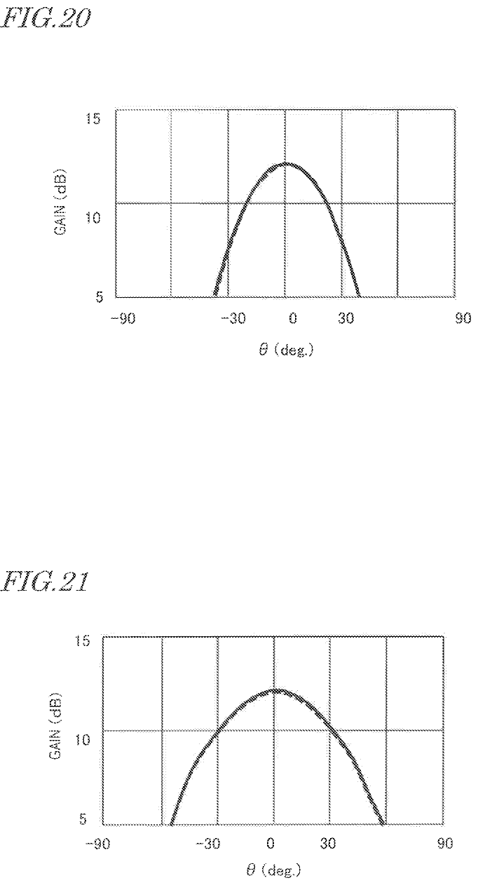

The results of calculation of a characteristic of the planar array antenna of the second embodiment are described. The s parameter was measured according to the size and physical properties shown in FIG. 18 and TABLE 1. The VSWR characteristic is shown in FIG. 19. The radiation characteristic of the planar array antenna is shown in FIG. 20 and FIG. 21. For the sake of reference, the characteristic of a planar array antenna in which the distances between the opposite end portions of the strip conductor 14 and the first ground conductor layer 13 are equal is determined and shown in these graphs. In FIG. 19 through FIG. 21, solid lines represent the characteristic of the inventive example while broken lines represent the characteristic of the reference example.

TABLE 1

| PROPERTIES | VALUES |
|---|---|
| dielectric constant | 6 |
| tanδ | 0.0018 |
| material and size of electrode | Ag, 12 μm, 4 μm |
| pitch of unit cells | x: 5.357 mm, y: 5.357 mm |
| number of unit cells | 6 (3 × 2) |

As shown in FIG. 19, for example, in the reference example, VSWR is not more than 1.5 when the frequency is from about 27.2 GHz to about 28.8 GHz, while in the inventive example, VSWR is not more than 1.5 when the frequency is from about 26.4 GHz to about 29.5 GHz. According to the planar antenna of the second embodiment, it can be seen that an electromagnetic wave can be transmitted while reflection is suppressed in a broad band.

FIG. 20 and FIG. 21 show the gain characteristic of an electromagnetic wave radiated from the planar array antenna of Inventive Example 1. FIG. 20 and FIG. 21 show the characteristic in the HZ plane and the characteristic in the yz plane, respectively, where the coordinate system is set as shown in FIG. 1. The z axis, i.e., the normal direction of the upper surface 40u, is 0°. The +x axis and −x axis directions or the +y axis and −y axis directions correspond to +90° and −90° of θ.

It can be seen from these graphs that, in the planar antenna of the inventive example, the gain was the same in some portions of the range shown in the graphs but the gain improved by about 0.2 dB in other portions of the range, and on average, the gain improved as compared with the reference example.

Thus, it can be seen from these calculation results that the planar antenna of the inventive example is capable of transmitting and receiving electromagnetic waves in broad bands and improving the gain.

### REFERENCE SIGNS LIST

11 radiation conductor

12 planar conductor layer

12c second slot

13 first ground conductor layer

13c first slot

14 strip conductor

14c first end portion

14d second end portion

15 second ground conductor layer

15d opening

16, 17, 18 via conductor

22 via conductor portion.

21 to 31 planar strip portion

40, 40′ multilayer ceramic structure

40a, 40b, 40e ceramic layer

40u, 40′u upper surface

40v lower surface

41 dielectric

41c dielectric layer

50, 50′ unit cell

51, 51′ radiation portion

52, 52′ power supply portion

71 passive-parts pattern

72 wiring pattern

73 electrically-conductive via

74 to 76, 92 electrode

81 solder bump

82 passive part

83 active part

91 circuit board

101 planar array antenna

102, 102′, 103 multilayer ceramic substrate

104 wireless communication module

1. A planar array antenna comprising a plurality of unit cells which are one-dimensionally or two-dimensionally arranged, each of the unit cells including
a radiation portion which includes a radiation conductor and a first ground conductor layer spaced away from the radiation conductor and having a first slot, and
a power supply portion which includes a strip conductor,
wherein the strip conductor has a first end portion which is supplied with an electric power from an external device and a second end portion which is spaced away from the first end portion in a longitudinal direction, and
a distance between the first end portion and the first ground conductor layer is different from a distance between the second end portion and the first ground conductor layer.

2. The planar array antenna of claim 1, wherein the power supply portion includes a second ground conductor layer spaced away from the strip conductor, the strip conductor being located between the first ground conductor layer and the second ground conductor layer.

3. The planar array antenna of claim 2 wherein, in each of the unit cells, the radiation conductor and the first slot are aligned in a layer stacking direction.

4. The planar array antenna of claim 2, wherein a longitudinal direction of the strip conductor and a longitudinal direction of the first slot are transversal with each other.

5. The planar array antenna of claim 2, wherein a distance between the second end portion and the first ground conductor layer is shorter than a distance between the first end portion and the first ground conductor layer.

6. The planar array antenna of claim 5, wherein
the strip conductor includes a plurality of planar strip portions and at least one via conductor portion,
the plurality of planar strip portions are located between the first end portion and the second end portion such that a longitudinal direction of each of the planar strip portions is in accord with a longitudinal direction of the strip conductor, and at least one of opposite ends of each of the planar strip portions is connected with one of opposite ends of an adjacent planar strip portion via one of the plurality of via conductor portions, and
in the strip conductor, one of two adjoining planar strip portions located on the second end portion side is closer to the first ground conductor layer than the other planar strip portion which is on the first end portion side.

7. The planar array antenna of claim 6, wherein the plurality of planar strip portions have equal widths in a direction perpendicular to the longitudinal direction.

8. The planar array antenna of claim 6 wherein, in at least a pair of adjoining two of the plurality of planar strip portions, a width in a direction perpendicular to the longitudinal direction of the planar strip portion on the second end portion side is greater than a width in a direction perpendicular to the longitudinal direction of the planar strip portion on the first end portion side.

9. The planar array antenna of claim 6, wherein a width of at least one of the plurality of planar strip portions is greater on the second end portion side than on the first end portion side.

10. The planar array antenna of claim 6, wherein the plurality of planar strip portions are arranged parallel to the first ground conductor layer.

11. The planar array antenna of claim 5, wherein
the strip conductor includes a planar strip portion,
a longitudinal direction of the planar strip portion is in accord with the longitudinal direction of the strip conductor, and
one of opposite ends of the planar strip portion on the second end portion side is closer to the first ground conductor layer than the other end on the first end portion side.

12. The planar array antenna of claim 2, wherein the radiation portion is located between the radiation conductor and the first ground conductor layer so as to be spaced away from the radiation conductor and from the first ground conductor layer, the radiation portion further including a planar conductor layer which has a second slot.

13. The planar array antenna of claim 12 wherein, in each of the unit cells, the radiation portion includes a plurality of the planar conductor layers.

14. The planar array antenna of claim 12, wherein the second slot has the same shape as the first slot.

15. The planar array antenna of claim 12, wherein the second slot has a different shape from the first slot.

16. (canceled)

17. The planar array antenna of claim 12, wherein the planar conductor layer is electrically coupled with the first ground conductor layer or the second ground conductor layer.

18. The planar array antenna of claim 12, wherein the planar conductor layer is a floating conductor layer.

19. The planar array antenna of claim 2, wherein
the power supply portion of each of the unit cells further includes a plurality of via conductors, and
the plurality of via conductors are connected with the first ground conductor layer and the second ground conductor layer and arranged so as to surround the strip conductor.

20. The planar array antenna of claim 2, wherein each of the unit cells includes a multilayer ceramic structure, and at least the planar conductor layer, the first ground conductor layer, the second ground conductor layer and the strip conductor are buried in the multilayer ceramic structure.

21. A wireless communication module comprising:
the planar array antenna as set forth in claim 20; and
an active part electrically coupled with the planar array antenna.
